(19) United States
(12) Patent Application Publication
(10) Pub. No.: US 2024/0314904 A1
(43) Pub. Date: Sep. 19, 2024

(54) LIGHTING ARRANGEMENT, PIXEL ARRANGEMENT AND DISPLAY

(71) Applicant: ams-OSRAM International GmbH, Regensburg (DE)

(72) Inventors: Julia STOLZ, Dresden (DE); Igor STANKE, Regensburg (DE)

(21) Appl. No.: 18/272,920

(22) PCT Filed: Jan. 19, 2022
(86) PCT No.: PCT/EP2022/051084

§ 371 Date: Jul. 18, 2023

(30) Foreign Application Priority Data
Jan. 19, 2021 (DE) 10 2021 100 998.7

(51) Int. Cl. H05B 45/325; H01L 25/075; H01L 27/15; H01L 33/32

(52) U.S. Cl. CPC H05B 45/325; H01L 25/0753; H01L 27/156; H01L 33/32

(57) ABSTRACT

A light arrangement includes a first, a second and a third current path connected in parallel to one another between a common supply line for supplying a supply potential and a reference potential line with a reference potential. Each of the three current paths includes a controllable current source. The first current path has a first optoelectronic semiconductor component for generating light with a first central wavelength, and the second current path has a second optoelectronic semiconductor component for generating light with a second central wavelength. The third current path includes two series-connected third optoelectronic semiconductor components, each designed to generate light at a third central wavelength, the third central wavelength being longer than the first and second central wavelengths.

The present application claims the priority of German application DE 10 2021 100 998.7 of Jan. 19, 2021, the disclosure content of which is hereby incorporated by reference in its entirety.

The invention relates to a light arrangement, a pixel arrangement comprising such light arrangements, and a display.

### BACKGROUND

In the case of modern displays, inter alia for the television sector, there, in addition to a good black level, the brightness is also of primary importance to the customer.

While the brightness of such displays should be high enough to ensure that the image is sufficiently visible even in open and light-flooded rooms, high brightness is required for the automotive sector, especially for good readability against the light. Since, among other things, modern displays are also non-reflective or can have covers with additional functionality, high brightness is also necessary here in order to be able to integrate such displays behind filters, semi-transparent mirrors and other covers.

The maximum brightness of a display is in turn limited by the maximum permissible power dissipation. The higher the brightness, the higher the power dissipation, so that the heat generated must also be dissipated. In the automotive sector, this is regulated so that the power density there is limited to 400 W/m² according to the DFF specification.

In the case of a display module, i.e. a module with a large number of pixels arranged in rows and columns, the power consumed and thus the heat output is essentially determined by the current per pixel. It should be noted that with current components, which are implemented in pixels, and the material systems used, the brightness requirements with regard to customer wishes with the limited power density or also the heat loss to be expected can only be realized with difficulty or hardly at all.

In addition, displays, especially in the automotive sector, have to meet high requirements in terms of temperature stability and the service life of the individual pixels and optoelectronic semiconductors. These vary considerably depending on the material system used, so that selective failures can occur over the lifetime of a display, especially of optoelectronic semiconductor components for red light. In addition, the high losses during operation of a display lead to color shifts.

Thus, there is a need to meet these different requirements and to achieve a good balance between brightness and power consumption or power dissipation, thereby increasing temperature stability and lifetime.

### SUMMARY OF THE INVENTION

In displays with RGB pixels, the pixels are subdivided into sub-pixels which are constructed with optoelectronic semiconductor components and emit light of a different central wavelength during operation. A central wavelength is understood herein as the wavelength at which a light intensity is greatest in an operation of an optoelectronic semiconductor component.

An optoelectronic semiconductor component is also referred to as a light-emitting diode and, in particular, as a p-LED. Displays, especially smaller displays, which nevertheless should offer high resolution, are often realized with such p-LEDs. Compared to conventional light-emitting diodes, a p-LED is characterized by a significantly smaller edge length in the range of less than 100 μm and in particular less than 30 μm, for example in the range of 4-15 μm. It was found that p-LEDs for the generation of red light (in the following simplified called red p-LEDs or red light emitting diodes) have a lower efficiency due to the different material system compared to u-LEDs for light in the green or blue range (in the following simplified called green or blue u-LEDs or green or blue light emitting diodes).

In addition, the small edge length relative to the small light emitting surface leads to a poor ratio of perimeter to area of the respective opto-electronic semiconductor device. The reason for this is the defect density, which is increased in the area of the circumference of the surface in particular, so that non-radiative recombination is preferred there over radiative recombination of charge carriers. Accordingly, this loss mechanism is particularly pronounced for u-LEDs and low current densities. In the case of red-LEDs, this is even more pronounced due to the material system and the associated greater free path length, which results in significantly lower efficiency compared to green or blue LEDs.

In order to nevertheless generate the desired brightness, it is necessary in conventional systems to amplify the current flow through the corresponding u-LED. However, in addition to the increased brightness, this also increases the power dissipation. In addition, the InGaAlP material system used for red light-emitting diodes is particularly susceptible to temperature fluctuations, which lead to greater color shifts when the respective u-LED is operated with this material system. In addition to the previous approaches to achieve a higher display brightness, for example by improving the LED efficiency by means of different epitaxy and chip designs, as well as improving the light extraction via cavities and optical coatings of the display, the inventors have created a further possibility to improve the brightness, in particular for red light-emitting diodes of a pixel.

The inventors exploit the fact that a threshold voltage Vth as well as a maximum forward voltage Vf between InGaAlP-based optoelectronic semiconductor components for red light differs from InGaN-based optoelectronic semiconductor components for green and blue light. A supply voltage of a pixel is determined among other things by the maximum forward voltage Vfmax, which is the highest for driving optoelectronic semiconductor components for blue light. The same applies to the saturation voltage Vsat of such a pixel at a maximum current. The supply current of an entire pixel is in turn composed of the individual currents for the red, green and blue subpixels and thus for the light-emitting diodes of the corresponding subpixels.

In order to reduce the power dissipation at the same supply voltage for the respective subpixels, the inventors propose to connect two optoelectronic components or two light-emitting diodes in series instead of a single optoelectronic semiconducting component for a red subpixel. In other words, instead of one red light-emitting diode, two red light-emitting diodes are now connected in series for each pixel, while only one light-emitting diode continues to be used for the green and blue subpixels. An RGB pixel is thus replaced by an RRGB pixel. The inventors take advantage of the fact that a voltage drop across the two red light-emitting diodes corresponds to about 1V above the voltage drop in the current path of the blue or green light-emitting diodes. With the same supply voltage for all subpixels, this significantly reduces the power dissipation in contrast to previous solutions that only drive a red light emitting diode with a higher current, since the current driver for the current path with the red light emitting diodes no longer has to convert the remaining voltage into thermal power. At the same time, the current flow through this current path can be reduced while still increasing or maintaining the brightness at the desired level due to the two red light emitting diodes connected in series.

In one aspect, a light arrangement is proposed, in particular for a pixel, comprising a first, a second and a third current path connected in parallel between a common supply line for supplying a supply potential and a reference potential line with a reference potential. Each of the three current paths comprises a controllable current source. In the first current path, a first optoelectronic semiconductor component for generating light with a first central wavelength is arranged, and in the second current path, a second optoelectronic semiconductor component for generating light with a second central wavelength is arranged. The third current path comprises two series-connected third optoelectronic semiconductor components, each of which is designed to generate light with a third central wavelength, the third central wavelength being longer than the first and second central wavelengths.

As a result, a voltage drop in the respective current paths is more closely matched, increasing efficiency while reducing power dissipation, especially in the current path for the third central wavelength. Likewise, the lifetime of the red opto-electronic devices or light emitting diodes is also increased and a color change due to heating is reduced. In some aspects, a temperature compensation circuit can also be constructed much more simply, which in turn saves cost and space. The third central wavelength is in the red region of the spectrum, i.e., between 610 nm and 660 nm. In another aspect, exactly one blue or green light emitting diode is driven in one operation per pixel of a dis-play, while two red light emitting diodes are driven in one operation per pixel. In one aspect, each current path of the light arrangement forms a sub-pixel of a pixel.

In another aspect, a control circuit is provided to which each of the controllable current sources is connected. The control circuit is configured to control each of the current sources, in particular as a function of the supply potential. The dependence allows fluctuations or changes on the supply line to be detected and compensated for, so that a constant brightness is achieved even over a plurality of such lighting arrangements. In one aspect, the control circuitry is configured to generate and output a pulse width modulated signal to the controllable current sources.

In another aspect, the controllable current source of at least the third current path comprises a current drive transistor having a control terminal connected to the control circuit. The other current paths may also each include a current driver transistor. Some or even all of the current drive transistors of the respective current paths may have the same structure, thus reducing cost and effort in manufacturing.

Another aspect deals with redundancy, since individual LEDS can fail during production. Therefore, in one aspect, a backup current path is provided with a controllable current source and a further, third optoelectronic semiconductor component. The backup current path is associated with the third current path, whereby the third optoelectronic semiconductor component is then designed to generate light at the third center wavelength. Likewise, each of the other current paths, i.e. the first and second current paths, can be assigned a reserve current path constructed in the same way. This comprises in each case a controllable current source and an optoelectronic semiconductor component which emits green or blue light during operation. The respective backup current path is activated if a fault occurs in the current path assigned to the backup current path. Then, the associated current path is disabled and the drive circuit regulates the current source of the reserve current path.

In one aspect, the controllable current source of the backup current path comprises a current drive transistor having a control terminal connected to the control circuit. The current driver transistor may be configured to provide a current that is approximately twice the current provided by the current driver transistor of the third current path while being driven by the control circuit at substantially the same rate.

In another aspect, the optoelectronic semiconductor components of the first and second current paths, as well as an optoelectronic semiconductor component of the third current path, are connected to the common supply line at the anode side. This design corresponds to a common anode design of a lighting device. The optoelectronic semiconductor components of the first and second current paths, as well as an optoelectronic semiconductor component of the third current path can also be connected with their cathode to the reference potential line, which corresponds to a common cathode structure.

The various optoelectronic semiconductor components are configured to generate light at different wavelengths. Thus, in one aspect, a threshold voltage of one of the third optoelectronic semiconductor components may be smaller than a threshold voltage of the first and second semiconductor optical devices. Similarly, in one aspect, a forward voltage of one of the third optoelectronic semiconductor components may be smaller than a forward voltage of the first and second semiconductor optical devices.

Other aspects deal with the structure and configuration of the optoelectronic semiconductor components. In one aspect, a material system of the third optoelectronic semiconductor components differs from a material system of the first and second optoelectronic semiconductor components. For example, the third optoelectronic semiconductor components may have a material system based on InGaAlP, and the first and second optoelectronic semiconductor components may have a material system based on InGaN.

In one aspect, the first, second and third optoelectronic semiconductor components are u-LEDs. These have an edge length of less than 100 μm and in particular less than 30 μm. The emitting area of such devices may be smaller than 10000 μm² and in the range of 100 μm² to 2000 μm².

Another aspect deals with a pixel arrangement. This comprises at least a first pixel comprising a first light arrangement according to one of the previous aspects and at least a second pixel comprising a second light arrangement according to one of the previous aspects. The two series-connected third optoelectronic semiconductor components of the third current path in the first and in the second luminous device are used together, i.e. they are the same optoelectronic semiconductor components. In this embodiment, the number of third optoelectronic semiconductor components used can thus be reduced.

A pixel arrangement according to the proposed principle thus comprises a first pixel comprising a light arrangement according to any one of the preceding claims, and a second pixel comprising:
a fourth and a fifth current path connected in parallel to each other between the common supply line and the reference potential line; wherein the fourth and fifth current paths each comprise a controllable current source and the fourth current path comprises a fourth optoelectronic semiconductor component for generating light at the first central wavelength and the fifth current path comprises a fifth optoelectronic semiconductor component for generating light at the second central wavelength;
a controllable current source connected on the input side to the common supply line and having a current output connected to the third current path of the light arrangement third current path for supplying power to the two series-connected third optoelectronic semiconductor components.

Another aspect relates to a display comprising a plurality of pixels arranged in rows and columns and individually controllable, the pixels each comprising a lighting device according to any one of the preceding claims. Alternatively, each two pixels adjacent in a row or column may comprise a pixel array according to the principle of shared third optoelectronic semiconductor components as shown above.

### BRIEF DESCRIPTION OF THE DRAWINGS

Further aspects and embodiments according to the proposed principle will become apparent with reference to the various embodiments and examples described in detail in conjunction with the accompanying drawings.

FIG. 1A shows a first embodiment illustrating some aspects of the proposed principle

FIG. 1B shows a second embodiment illustrating some aspects of the proposed principle;

FIG. 2 shows a section of a third embodiment illustrating further aspects according to the proposed principle;

FIG. 3 illustrates a section of a fourth embodiment with further aspects according to the proposed principle;

FIG. 4 illustrates a section of the fourth embodiment in a realization with different polarity;

FIG. 5 is an embodiment of a fifth embodiment with further aspects according to the proposed principle;

FIG. 6 is a schematic representation of a display with a plurality of pixels arranged in rows and columns to explain some aspects of the proposed principle.

### DETAILED DESCRIPTION

The following embodiments and examples illustrate various aspects and combinations thereof according to the proposed principle. The embodiments and examples are not always to scale. Likewise, various elements may be shown enlarged or reduced in size to emphasize individual aspects. It goes without saying that the individual aspects and features of the embodiments and examples shown in the figures can be readily combined with each other without affecting the principle of the invention. Some aspects have a regular structure or shape. It should be noted that minor deviations from the ideal shape may occur in practice, but without contradicting the idea of the invention.

Individual switching elements are shown schematically, e.g. as bipolar transistors or as transistors of a certain conductivity type. However, it is understood that this is not meant to be restrictive. In general, the circuits shown can also be realized with different components, unless otherwise stated. Bipolar transistors can be replaced by field effect transistors, switches can be replaced by field effect transistors. Polarity can often be reversed, for example by replacing npn or NMOS transistors with pnp or PMOS transistors.

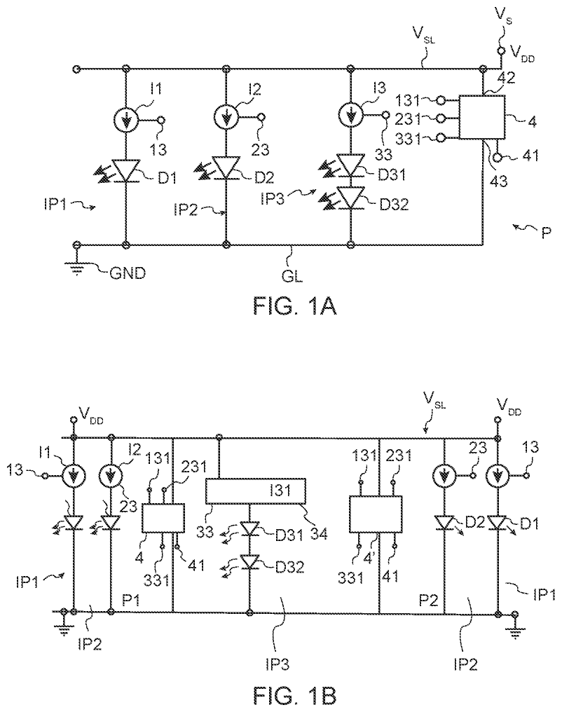

FIG. 1A shows an embodiment of a pixel in schematic view, which realizes some aspects of the proposed principle. The pixel P comprises a supply line VSL, which is designed as a common supply line for a drive circuit 4 and the three current paths IP1, IP2 and IP3. A supply potential VDD is applied to the supply line VSL when the pixel is in operation. Likewise, the pixel P comprises a reference potential line GL, simplified also referred to as ground line GL, which is connected to a reference or ground potential GND. The individual current paths IP1, IP2 and IP3 for the green, blue and red subpixels are thus connected in parallel between the supply line VSL and the reference potential line GL.

The current path IP1 comprises a controllable current source I1 with a control input 13, as well as a first series-connected optoelectronic semiconductor component D1. This is also referred to as a light-emitting diode LED and is implemented, for example, as a u-LED. In operation, the light emitting diode D1 generates light with a central wavelength, for example in the blue range. The second current path comprises a controllable current source I2 with a control input 23 and a second light emitting diode D2 connected to the source. This generated light with a central wavelength in the green spectrum and is thus also referred to as a green light-emitting diode. Finally, a third current path IP3 is also provided. This also contains a controllable current source I3 with a regulation input 33. Two light emitting diodes D31 and D32 are now connected to this in series. These light-emitting diodes D31 and D32 have the same structure and generate a central wavelength in the red range during operation. In other words, it is proposed according to the invention to design the subpixel for generating red light with two identical series-connected light-emitting diodes instead of a single light-emitting diode.

The voltage drop, for example the maximum forward voltage V_{f} of these two light emitting diodes is the same and the current through them is also the same. Depending on the design of the current source I3 in the current path IP3, V_{DD}=V_{Ip3}+2 V_{f}.

Compared to a conventional current path with only one red light emitting diode, the voltage drop across the current source is thus lower for the same supply voltage V_{DD}. This reduces the power dissipation, because the “excess voltage”, i.e. the part of V_{DD} that does not drop across the light emitting diodes, must otherwise be converted into heat in the current source.

At the same time, the same current I from the current source IP3 flows through both light emitting diodes D31 and D32. A smaller current is therefore required to generate a specified brightness value for the red current path, since both light emitting diodes contribute to the brightness value here. In comparison, a current path with only one red light emitting diode requires about twice the current to produce the same brightness. A lower current through the light-emitting diodes thus also produces lower power dissipation here, so that they heat up less. This also means that a possible color shift due to temperature is less pronounced. If two red LEDs are used in series, the red subpixel requires a smaller current for the same target brightness. At constant efficiency, only half the current would be required. In the low current range, the typical sublinear current dependence of the efficiency can lead to somewhat higher current values, but there is still an advantage in terms of power consumption. The supply voltage V_{DD} has to be increased only slightly, if at all, since V_{f} for red LEDs is about 1V below V_{f} for green and blue LEDs. Thus, for a given target brightness, less input power is required and the overall efficiency of the display increases. Less waste heat is generated.

The pixel P further comprises a drive circuit 4 having three control outputs 131, 231 and 331, each connected to one of the control inputs 13, 23 and 33 of the controllable current sources I1, I2 and I3. The drive circuit 4 is also connected on the input side to the supply line VSL for supply. The supply potential Von at input 42 is not only used to supply the drive circuit 4, but is also processed in the control circuit 4 to generate a predetermined brightness in the respective subpixels. In other words, the drive circuit 4 is configured to sense variations in the supply potential V_{DD} on the supply line VSL and to drive the controllable current sources I1 to I3 accordingly so that the desired current flow and desired voltage drop across the individual light emitting diodes D1, D2, D31 and D32 is achieved. To generate the respective color for the pixel P, a control input 41 is also provided for the control circuit 4, to which a digital or analog control signal is applied to control the respective color.

FIG. 1B shows a schematic representation of a further embodiment in which it is intended to use the current path IP3 to generate red light in two adjacent pixels P1, P2 simultaneously. As illustrated, the current paths IP1 and IP2 are designed separately for the respective pixels P1 and P2. On the other hand, the current path IP3 with its controllable current source I31 and the two light emitting diodes D31 and D32 connected in series are used together. For this purpose, the controllable current source I31 in this embodiment comprises a first control input 33 and a second control input 34. The first control input 33 is connected to the drive circuit 4 of the pixel P1 and the second control input 34 is connected to the drive 4′ of the pixel P2. Thus, in one operation, a red color is represented by the diodes D31 and D32 for the pixel P1 and P2, respectively, mixed and given as the sum of the two control circuits, respectively.

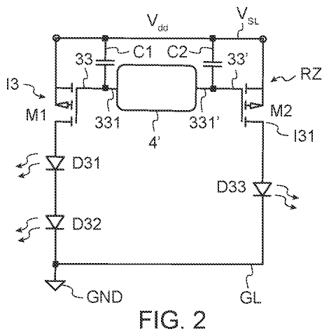

FIG. 2 shows a further aspect of the arrangement according to the invention, here limited to a subpixel for the red color. To increase the yield in the production of displays, redundant light-emitting diodes are to be installed so that redundant components can take over this function in the event of failure of a light-emitting diode in the current path for the red subpixel. In this design, the subpixel with a current path IP3 is supplemented by a further redundant current path RZ. The redundant current path RZ comprises an adjustable current source I31 and a single light emitting diode D33 connected to it. This is identical in design to the light-emitting diodes D31 and D32 of the current path IP3 for generating red light.

The controllable current sources I3 and I31 are each formed by a current driver transistor M1 and M2. The control terminal 33 of the current driver transistor M1 is connected to the terminal 331 of the drive circuit 4′. Correspondingly, the control terminal 33′ of the current driver transistor M2 is connected to the terminal 331′ of the drive circuit 4′. For better coupling and correction of fluctuations on the supply line VSL, two condensers C1 and C2 are provided respectively, which are coupled between the supply line VSL and the control outputs 331 and 331′ of the drive circuit 4′.

In an operation of this arrangement, the current flow through the current path IP3 is significantly lower when the light emitting diodes D31 and D32 are functioning for a given total brightness. In order to be able to compensate for the failure of this current path IP3, it is necessary that the current driver transistor in the redundant current path RZ generates the same brightness together with the light emitting diode D33 at the same supply voltage. For this purpose, transistor M2 should generate approximately twice the current at the same supply voltage. In such a case, the current flowing through the redundant current path RZ is approximately twice that which would flow through the current path I3 in normal operation. Accordingly, the light emitting diode D33 lights up with approximately the same brightness as the light emitting diodes D31 and D32 with the reduced current flow.

Although this increases the power dissipation in the redundant current path RZ, the number of redundancy paths used in displays with this design is low due to the high yield. As a result, only a few LEDs D31 or D32 fail in current path I3, so that the increased power dissipation due to the small number of redundancy paths used is only insignificantly noticeable.

For the design and layout of the regulating transistor M1, there are two possibilities depending on the technology used. When using thin-film technology TFT with large dimensions, the subpixel does not require more voltage. For the light emitting diodes to operate in the saturation region of the regulating transistor M1, V_{ds} must be >=V_{gs}−Vₜₕ, where V_{ds} represents the drain-source voltage and V_{gs} the gate-source voltage. Connecting the light emitting diodes in series reduces the current required to achieve the target brightness and thus reduces V_{gs}. The supply voltage can be left essentially constant if the forward voltage and gate-source voltage for the regulating transistor are approximately equal to the red current path for both red light-emitting diodes. This relationship can be expressed:

$${V}_{f \_ blue} + ( {V}_{gs} ( {I}_{\_ blue , max} ) - {V}_{th} ) <= 2 * {V}_{f \_ red} + ( {V}_{gs} ( {I}_{\_ red , max} ) - {V}_{th \_ red} ) .$$

V_{th_blue} and V_{th_red} are the respective threshold voltages for the red and blue pixels. The gate-source voltages are those for the corresponding current driver transistors for the red and blue current paths, respectively. By selectively choosing the channel width and channel length for the current driver transistor formed in TFT in the red current path, the above relationship can be achieved.

The current driver transistor for the red current path can also be made smaller under certain conditions. By connecting the red light emitting diodes in series, the required operating point is achieved with a smaller current. Since less current is required due to the series connection, the current driver transistor for the red current path can also be reduced in size accordingly. This means that the gate-source voltage V_{gs} required to achieve the new target current via the current drive transistor for the red current path remains approximately constant. In an example calculation, the required increase in supply voltage DVDD assuming that Vas, sat is approximately constant for both the red and blue subpixels is as follows:

$${DV}_{DD} = 2 * {V}_{f \_ red} - {V}_{f \_ blue} = 2 * 1.8 V - 2.8 V = 0.8 V .$$

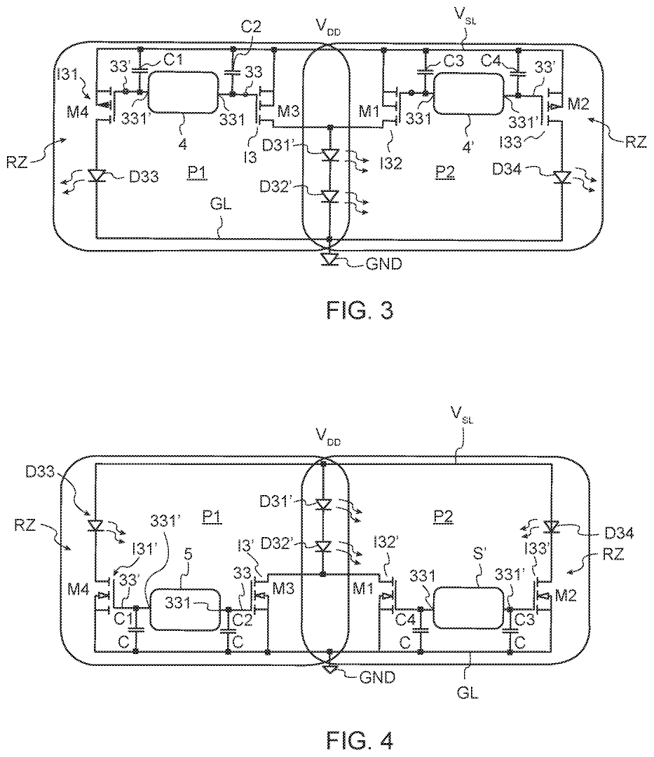

FIG. 3 now shows an embodiment of the proposed principle for the red subpixel, where the red subpixel is shared in two pixels P1 and P2. In this respect, this shared use is similar to FIG. 1A, but now a redundancy path RZ is also provided for each subpixel.

Accordingly, the red subpixel for pixel P1 comprises a redundancy path RZ with a current source I31 and a light emitting diode D33 connected in series therein. Another current source I3 is part of a current path shared by pixels P1 and P2 with two light emitting diodes D31′ and D32′. These two series-connected light-emitting diodes are also driven by the current source I32 of the further current path for the red subpixel of pixel P2. Pixel P2 also includes a redundancy branch RZ with its own current source I33 and a light emitting diode D34 arranged therein. As shown, the subpixels of pixel P1 and pixel P1 share both light emitting diodes D31 and D32, respectively. This results in the same number of light-emitting diodes as in conventional displays when two redundancy paths RZ are used for the respective pixels. In this embodiment, the number of light-emitting diodes for the red sub-pixels is not significantly increased.

FIG. 4 shows an embodiment similar to that shown in FIG. 2 for the red subpixels of two pixels P1 and pixel P2. In contrast to the embodiment in FIG. 3, the circuit is now constructed in NMOS technology so that the diodes D31, D32 of the shared current path and the diodes of D33 and D34 of the respective redundancy paths RZ are connected to the supply line VSL on the anode side. The current sources I31′, I3′, I32′ and I33′ are each connected between the diodes and the ground potential line GL. In contrast to the previous embodiment, the current driver transistors M1, M2, M3 and M4 are now implemented in NMOS technology and not in PMOS technology.

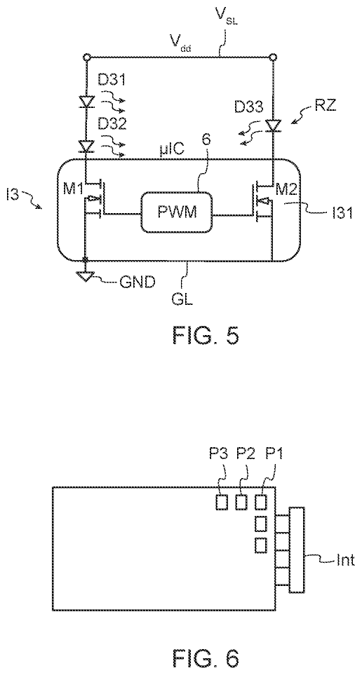

Finally, FIG. 5 shows another embodiment of a subpixel for the red color, with a current path IP3 and an associated redundancy path RZ. Here, too, the design is based on NMOS technology, so that the anodes of the respective diodes D31 and D33 are connected to the supply line VSL. A pulse-width modulation circuit 6 is used here as the drive circuit, which outputs a pulse-width modulated signal to the control terminals of the current driver transistors M1 and M2.

FIG. 6 illustrates a schematic embodiment of a display, which implements the pixels in the manner illustrated herein. The display comprises several pixels P1, P2 and P3 arranged in rows and columns, each of which has a subpixel for generating three different colors. Depending on the color space, four subpixels can also be provided for generating different colors. The individual pixels are realized in the embodiments presented here. For example, two neighboring pixels each have a common subpixel for generating the red color. For this purpose, two vertically, i.e. column-wise adjacent pixels, but also two horizontally, i.e. row-wise adjacent pixels can each use their subpixel for the red color in common. In such an embodiment, the total number of red light-emitting diodes is kept constant compared to conventional displays. Likewise, the individual subpixels can each have assigned redundancy branches, so that errors in production or in the assembly of the individual light-emitting diodes can be compensated for by means of the redundant branches.

By the proposed use of two red light-emitting diodes in series, the red subpixel requires a smaller current for one pixel at the same target brightness. In the case of constant efficiency, only half the current would be required, whereas decreasing efficiency in the low current range leads to slightly higher current values. Accordingly, in the current path with two red light emitting diodes, the voltage increases by a forward voltage V_{f} for one light emitting diode. However, since this is significantly lower for red light-emitting diodes than the corresponding forward voltage for green and blue light-emitting diodes, the total supply voltage VDD only has to be increased slightly. Thus, less input power is required for a given target brightness and the overall efficiency of the display increases. Less waste heat is also generated. Another advantage is that the use of lower currents for the red light-emitting diodes means that the self-heating of the red light-emitting diodes is lower. As these have a stronger temperature dependence than corresponding green and blue LEDs due to the material system used, the lower current flow also improves the color stability of the display. In addition, the aging of the red LEDs is slowed down by the low current flow and the associated lower self-heating.

In production, various failures of individual light-emitting diodes now occur, so that the respective redundancy paths have to be activated in one operation. However, modern transfer processes have only low failure rates, especially for u-LEDS, so that the total redundancy paths to be used have little effect on the total power dissipation. This means that there is no need to use a further light emitting diode in the redundancy path for the red subpixel, thus saving space and reducing costs.

When current paths for the red subpixels are used together in two adjacent pixels, the costs and the required space are further reduced. This makes it possible to develop more complex circuits and displays with higher resolutions. Although red light is generated for each of two adjacent pixels, which reduces the contrast in the red range, this effect does not play a significant role due to the high color sensitivity of the eye in the green range. On the other hand, the light-emitting diodes for the red subpixels can be operated with a higher current on average when used simultaneously in neighboring pixels. Especially for the red light emitting diodes this allows a simpler operating point adjustment in the lowest range, as well as higher brightnesses and lower heat losses.

### REFERENCE LIST

13, 23, 33 Control input
33, 33′ Control connection
4 Control circuit
131, 231, 331 Control output
C1, C2, C3, C4 Capacitors
D1, D2 optoelectronic semiconductor component
D31, D32 optoelectronic semiconductor component
GL reference potential line
GND reference potential
I1, I2, I3 adjustable current source
I31, I32, I33 controllable current source
IP1, Ip2, Ip3 current path
INT interface
pixel
RZ redundancy path
VS supply connection
VSL supply line
VDD supply potential

1. A light arrangement, comprising:
a first, a second and a third current path which are connected in parallel with one another between a common supply line for supplying a supply potential and a reference potential line with a reference potential;
wherein each of the three current paths comprises a controllable current source;
wherein the first current path comprises a first optoelectronic semiconductor component for generating light with a first central wavelength, and the second current path comprises a second optoelectronic semiconductor component for generating light with a second central wavelength;
said third current path comprising two series-connected third optoelectronic semiconductor components each for generating light having a third central wavelength, said third central wavelength being longer than said first and second central wavelengths;
a backup current path comprising a controllable current source and a further, third optical half-waveguide component configured to generate light at the third central wavelength;
wherein the controllable current source of the backup current path comprises a current driver transistor having its control terminal connected to the control circuit and being adapted to provide a current which is approximately twice as high as a current provided by the current driver transistor of the third current path when driven substantially equally by the control circuit.

2. The light arrangement according to claim 1, wherein each current path of the light-emitting device forms a subpixel of a pixel.

3. The light arrangement according to claim 1, further comprising:
a control circuit connected to each of the controllable current sources and adapted to drive them, in particular in dependence on the supply potential.

4. The light arrangement according to claim 3, in which the control circuit is designed to generate and output a pulse-width modulated signal to the controllable current sources.

5. The light arrangement according to claim 3, in which the re-regulable current source of at least the third current path comprises a current driver transistor, the control terminal of which is connected to the control circuit.

6. The light arrangement according to claim 1, in which the optoelectronic semiconductor components of the first and second current paths, as well as an optoelectronic semiconductor component of the third current path, are connected on the anode side to the common supply line.

7. The light arrangement according to claim 1, wherein
a threshold voltage of the third optoelectronic semiconductor components is smaller than a threshold voltage of the first and second optoelectronic semiconductor components; or
a forward voltage of the third optoelectronic semiconductor components in an operation is smaller than a forward voltage of the first and second semiconductor optical devices.

8. The light arrangement according to claim 1, wherein a material system of the third optoelectronic semiconductor components is different from a material system of the first and second optoelectronic semiconductor components.

9. The light arrangement according to claim 1, wherein the third optoelectronic semiconductor components have a material system based on InGaAlP and the first and second optoelectronic semiconductor components have a material system based on InGaN.

10. The light arrangement according to claim 1, wherein the first, second and third optoelectronic semiconductor components have an edge length and/or an emitting area of less than 100 μm and in particular less than 30 μm.

11. A pixel arrangement having at least two light arrangements according to claim 1, the pixel arrangement comprising:
at least one first pixel comprising a first light arrangement of the at least two light arrangements; and
at least one second pixel comprising a second light arrangement of the at least two light arrangements,
wherein the two series-connected third optoelectronic semiconductor components of the third current path in the first light arrangement and in the second light arrangement are the same optoelectronic semiconductor components.

12. A display with a plurality of pixels arranged in rows and columns and individually controllable, wherein:
the pixels each comprise a light arrangement according to claim 1.

13. A display with a plurality of pixels arranged in rows and columns and individually controllable, wherein:
each two pixels adjacent in a row or in a column comprise a pixel arrangement according to claim 11.
